(19) United States
(12) Patent Application Publication
(10) Pub. No.: US 2025/0192425 A1
(43) Pub. Date: Jun. 12, 2025

(54) MULTI-CHANNEL BEAMFORMING CHIP-ANTENNA PACKAGE AND METHOD OF PACKAGING THE SAME

(71) Applicant: Electronics and Telecommunications Research Institute, Daejeon (KR)

(72) Inventors: Bong Hyuk PARK, Daejeon (KR); Sunwoo KONG, Daejeon (KR); SEUNG HUN WANG, Daejeon (KR); HUI DONG LEE, Daejeon (KR); Seunghyun JANG, Daejeon (KR); Jung Hwan HWANG, Daejeon (KR)

(21) Appl. No.: 18/754,500

(22) Filed: Jun. 26, 2024

(30) Foreign Application Priority Data
Dec. 12, 2023 (KR) 10-2023-0179280

(51) Int. Cl. H01Q 1/50; H01P 3/08; H03H 7/38

(52) U.S. Cl. CPC H01Q 1/50; H01P 3/081; H03H 7/38

(57) ABSTRACT

A multi-channel beamforming chip-antenna package is provided. The multi-channel beamforming chip-antenna package includes a multi-channel beamforming chip including a plurality of channels, a plurality of waveguides, and a plurality of coupling circuits configured to combine the plurality of channels with the plurality of waveguides, wherein each of the plurality of coupling circuits may include a matching circuit configured to combine a wire bonded to each of the plurality of channels and a microstrip line and a converting circuit configured to combine the microstrip line and the plurality of waveguides.

### CROSS-REFERENCE TO RELATED APPLICATION

This application claims the benefit of Korean Patent Application No. 10-2023-0179280, filed on Dec. 12, 2023, in the Korean Intellectual Property Office, the entire disclosure of which is incorporated herein by reference for all purposes.

### BACKGROUND

### 1. Field of the Invention

One or more embodiments relate to a multi-channel beamforming chip-antenna package and a method of packaging the same.

### 2. Description of the Related Art

Beamforming is technology for generating a radio wave beam having desired directivity in the wireless communication field. In the case of a frequency band or a sub-terahertz (THz) band of 100 gigahertz (GHz) or higher, the size of an antenna becomes very small and thus, beamforming may be implemented efficiently. Multi-channel beamforming is technology of using a plurality of antenna channels to form a more precise beam and improve signal strength and quality. A packaging method of minimizing the connection distance between a chip and an antenna and increasing efficiency of the antenna may be important. For example, packaging technology of integrating an antenna directly into a chip or a package, such as antenna on chip (AoC) or antenna on package (AoP), may be required.

The above description has been possessed or acquired by the inventor(s) in the course of conceiving the present disclosure and is not necessarily an art publicly known before the present application is filed.

### SUMMARY

Embodiments may provide a multi-channel beamforming chip-antenna package structure for long-distance transmission of signals.

Embodiments may provide a multi-channel beamforming chip-antenna package structure having low signal loss.

Embodiments may provide multi-channel beamforming chip-antenna packaging technology that enables long-distance transmission of signals and has low loss.

However, the technical aspects are not limited to the aforementioned aspects, and other technical aspects may be present.

According to an aspect, there is provided a multi-channel beamforming chip-antenna package including a multi-channel beamforming chip including a plurality of channels, a plurality of waveguides, and a plurality of coupling circuits configured to combine the plurality of channels with the plurality of waveguides, wherein each of the plurality of coupling circuits may include a matching circuit configured to combine a wire bonded to each of the plurality of channels and a microstrip line and a converting circuit configured to combine the microstrip line and the plurality of waveguides.

The matching circuit may include a first capacitance component line, a first inductance component line combined with the first capacitance component line, and a second capacitance component line combined with the first inductance component line.

A width of the first capacitance component line and a width of the second capacitance component line may be wider than a width of the first inductance component line.

The matching circuit may further include a matcher configured to perform impedance matching between the first inductance component line and the second capacitance component line.

The converting circuit may include a ground substrate formed in a first structure and a feeder including at least a portion of the microstrip line, wherein the feeder may be formed in a second structure which is able to engage with the first structure.

According to another aspect, there is provided a packaging method including combining a plurality of channels of a multi-channel beamforming chip and a matching circuit using a bond wire, combining the matching circuit and a converting circuit using a microstrip line, and combining the converting circuit and a plurality of waveguides.

The matching circuit may include a first capacitance component line, a first inductance component line combined with the first capacitance component line, and a second capacitance component line combined with the first inductance component line.

A width of the first capacitance component line and a width of the second capacitance component line may be wider than a width of the first inductance component line.

The matching circuit may further include a matcher configured to perform impedance matching between the first inductance component line and the second capacitance component line.

The converting circuit may include a ground substrate formed in a first structure and a feeder including at least a portion of the microstrip line, wherein the feeder may be formed in a second structure which is able to engage with the first structure.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram illustrating a multi-channel beamforming chip-antenna package according to an embodiment;

FIG. 2 is a side view of the multi-channel beamforming chip-antenna package of FIG. 1;

FIG. 3 is a diagram illustrating a matching circuit according to an embodiment;

FIG. 4 is a diagram illustrating a converting circuit according to an embodiment;

FIG. 5 is a schematic block diagram illustrating a multi-channel beamforming chip-antenna package according to an embodiment; and

FIG. 6 is a flowchart illustrating a packaging method according to an embodiment.

### DETAILED DESCRIPTION

The following detailed structural or functional description is provided as an example only and various alterations and modifications may be made to the embodiments. Accordingly, the embodiments are not construed as limited to the disclosure and should be understood to include all changes, equivalents, and replacements within the idea and the technical scope of the disclosure.

Although terms, such as first, second, and the like are used to describe various components, the components are not limited to the terms. These terms should be used only to distinguish one component from another component. For example, a first component may be referred to as a second component, and similarly the second component may also be referred to as the first component.

It should be noted that if one component is described as being “connected”, “coupled”, or “joined” to another component, a third component may be “connected”, “coupled”, and “joined” between the first and second components, although the first component may be directly connected, coupled, or joined to the second component.

The singular forms “a”, “an”, and “the” are intended to include the plural forms as well, unless the context clearly indicates otherwise. As used herein, “A or B”, “at least one of A and B”, “at least one of A or B”, “A, B or C”, “at least one of A, B and C”, and “at least one of A, B, or C,” each of which may include any one of the items listed together in the corresponding one of the phrases, or all possible combinations thereof. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms, including technical and scientific terms, used herein have the same meaning as commonly understood by one of ordinary skill in the art to which the present disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

As used in connection with the present disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

The term “unit” used herein may refer to a software or hardware component, such as a field-programmable gate array (FPGA) or an ASIC, and the “unit” performs predefined functions. However, “unit” is not limited to software or hardware. The “unit” may be configured to reside on an addressable storage medium or configured to operate one or more processors. Accordingly, the “unit” may include, for example, components, such as software components, object-oriented software components, class components, and task components, processes, functions, attributes, procedures, sub-routines, segments of program code, drivers, firmware, microcode, circuitry, data, databases, data structures, tables, arrays, and variables. The functionalities provided in the components and “units” may be combined into fewer components and “units” or may be further separated into additional components and “units.” Furthermore, the components and “units” may be implemented to operate on one or more central processing units (CPUs) within a device or a security multimedia card. In addition, “unit” may include one or more processors.

Hereinafter, the embodiments will be described in detail with reference to the accompanying drawings. When describing the embodiments with reference to the accompanying drawings, like reference numerals refer to like components and a repeated description related thereto will be omitted.

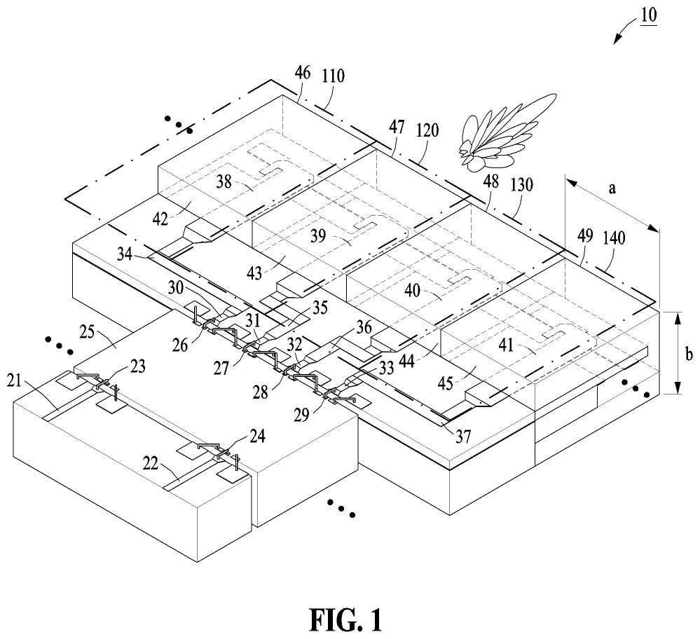

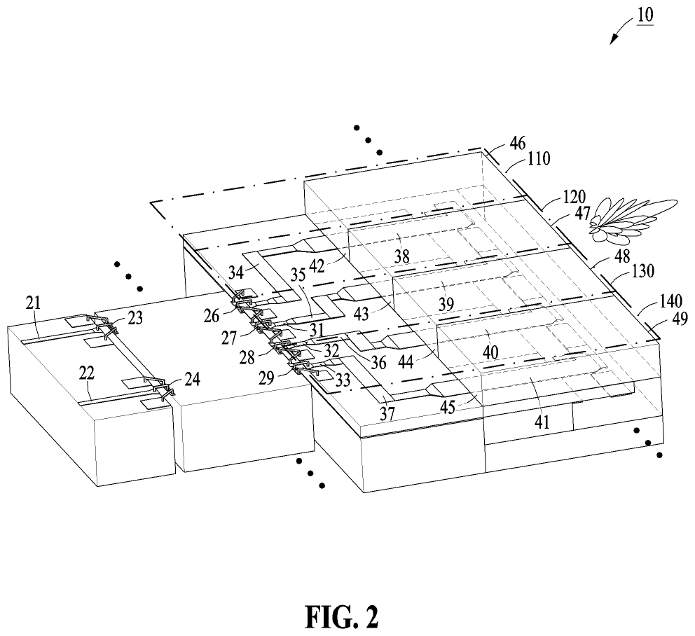

FIG. 1 is a diagram illustrating a multi-channel beamforming chip-antenna package according to an embodiment and FIG. 2 is a side view of the multi-channel beamforming chip-antenna package of FIG. 1.

Referring to FIGS. 1 and 2, according to an embodiment, a multi-channel beamforming chip-antenna package 10 may include a multi-channel beamforming chip (e.g., a multi-channel beamforming chip 25) including a plurality of channels, a plurality of waveguides (e.g., waveguides 46 to 49), and a plurality of coupling circuits (e.g., coupling circuits 110 to 140) for combining the plurality of channels with the plurality of waveguides (e.g., the waveguides 46 to 49). Each of the plurality of coupling circuits (e.g., the coupling circuits 110 to 140) may include a matching circuit (e.g., matching circuits 30 to 33) for combining a wire (e.g., bond wires 26 to 29) bonded to each of the plurality of channels and a microstrip line (e.g., microstrip lines 34 to 37) and a converting circuit (e.g., converting circuits 38 to 41) for combining the microstrip line (e.g., the microstrip lines 34 to 37) and the plurality of waveguides (e.g., the waveguides 46 to 49). FIGS. 1 and 2 show one multi-channel beamforming chip-antenna package 10, but the multi-channel beamforming chip-antenna package 10 may be expanded by increasing the number of channels of a beamforming chip or combining the same multi-channel beamforming chip-antenna packages. A package in which the multi-channel beamforming chip-antenna package 10 is expanded may function as an array antenna.

The multi-channel beamforming chip 25 according to an embodiment may include “n” channels. The multi-channel beamforming chip 25 may form a beam by combining signals received from each channel. The multi-channel beamforming chip 25 may receive a signal in which the center frequency is greater than or equal to a predetermined value. For example, the multi-channel beamforming chip 25 may receive a signal in which the center frequency is in a sub-terahertz band. The multi-channel beamforming chip 25 may receive input signals through an intermediate frequency (IF) microstrip line 21 and a local oscillator (LO) microstrip line 22. The IF microstrip line 21 may include a transmission line for transmitting a signal of the IF. The IF microstrip line 21 may be coupled to the multi-channel beamforming chip 25 by an IF bond wire 23. The LO microstrip line 22 may include a transmission line for stably transmitting a signal output from a local oscillator. The local oscillator may include an oscillator that may be used for frequency conversion and signal processing. The LO microstrip line 22 may be coupled to the multi-channel beamforming chip 25 by an LO bond wire 24.

The multi-channel beamforming chip 25 according to an embodiment may be coupled to a plurality of waveguides by a plurality of coupling circuits (e.g., the coupling circuits 110 to 140). Channels, a plurality of coupling circuits, and a plurality of waveguides of the multi-channel beamforming chip 25 may have a corresponding number. Hereinafter, for ease of description, it is assumed that the multi-channel beamforming chip 25 is a 4-channel beamforming chip including four channels. However, the multi-channel beamforming chip 25 is not limited to a 4-channel beamforming chip. For example, the multi-channel beamforming chip-antenna package 10 may include the multi-channel beamforming chip 25 including four channels, four waveguides (e.g., the waveguides 46 to 49), and four coupling circuits (e.g., the coupling circuits 110 to 140) for combining the four channels with the four waveguides (e.g., the waveguides 46 to 49), respectively.

The coupling circuits (e.g., the coupling circuits 110 to 140) according to an embodiment may include the bond wires 26 to 29, the microstrip lines 34 to 37, the matching circuits 30 to 33 for combining the bond wires 26 to 29 and the microstrip lines 34 to 37, and the converting circuits 38 to 41 for combining the microstrip lines 34 to 37 and the waveguides 46 to 49. The bond wires 26 to 29 may include conductive wires that are bonded so that the multi-channel beamforming chip 25 may be electrically connected to an external circuit (e.g., the coupling circuits 110 to 140). The bond wires 26 to 29 may be respectively connected to channels of the multi-channel beamforming chip 25 by wire bonding. For example, the bond wire 26, the bond wire 27, the bond wire 28, and the bond wire 29 may be respectively connected to the four channels of the multi-channel beamforming chip 25.

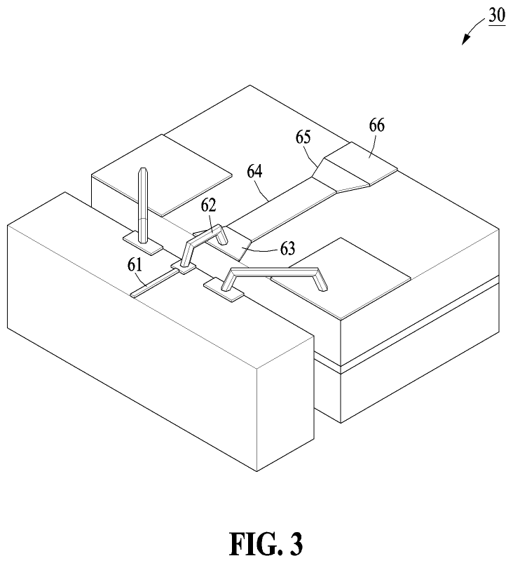

The matching circuits (e.g., the matching circuits 30 to 33) according to an embodiment may include circuits for matching the bond wires 26 to 29 and the microstrip lines 34 to 37. For example, the matching circuit 30, the matching circuit 31, the matching circuit 32, and the matching circuit 33 may be circuits for respectively matching the bond wire 26, the bond wire 27, the bond wire 28, and the bond wire 29 and the microstrip line 34, the microstrip line 35, the microstrip line 36, and the microstrip line 37. The matching circuits 30 to 33 are described in detail below with reference to FIG. 3.

Signals output from the multi-channel beamforming chip 25 to the bond wires 26 to 29 may be transmitted to the microstrip lines 34 to 37 through the matching circuits 30 to 33. The microstrip lines 34 to 37 may be transmission lines and may be formed of a metal plate on a circuit board (e.g., a printed circuit board (PCB)). The microstrip lines 34 to 37 may perform various functions such as antennas, filters, and combiners in high-frequency signal transmission.

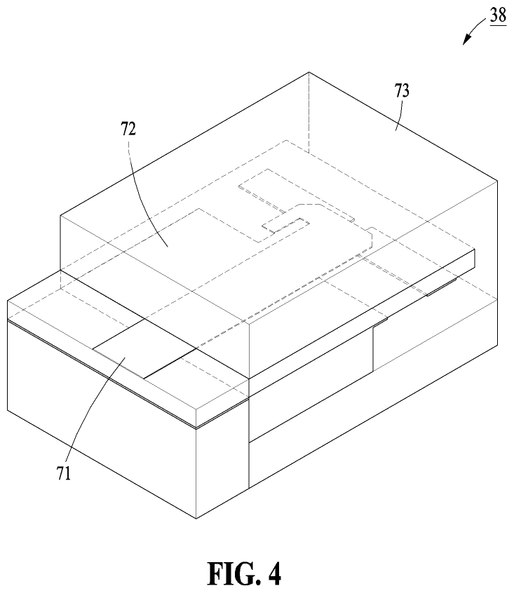

The signals output from the microstrip lines 34 to 37 may be converted by the converting circuits (e.g., the converting circuits 38 to 41). The converting circuits 38 to 41 may be configured as at least a part of the microstrip lines 34 to 37. The signals converted by the converting circuits 38 to 41 may be transmitted to the waveguides (e.g., the waveguides 46 to 49). The converting circuits 38 to 41 are described in detail below with reference to FIG. 4.

The signals converted by the converting circuits 38 to 41 may be transmitted to the waveguides (e.g., the waveguides 46 to 49). The waveguides 46 to 49 may be a hollow microwave transmission line including a metal plate. In order to overcome dielectric loss of a coaxial line, the waveguides 46 to 49 may be transmission lines that eliminate a conductor at the center and use air as an insulator. For example, the waveguides 46 to 49 may be configured in the form of a metal pipe and may be rectangular waveguides with a rectangular cross-section. The waveguides 46 to 49 may transmit energy as electromagnetic waves. The plurality of waveguides (e.g., the waveguides 46 to 49) may be arranged horizontally or vertically to function as an array antenna. Since the waveguides 46 to 49 perform the function of an antenna, the waveguides 46 to 49 may be used in a higher frequency band than a planar antenna.

FIG. 3 is a diagram illustrating a matching circuit according to an embodiment.

Referring to FIG. 3, according to an embodiment, the matching circuit 30 may be substantially the same as the matching circuit 30 described with reference to FIGS. 1 and 2. The matching circuit 30 may be substantially the same as the matching circuits 31 to 33, and FIG. 3 only shows the matching circuit 30 for ease of description. The matching circuit 30 may include a circuit for matching a bond wire 62 (e.g., the bond wires 26 to 29 of FIG. 1) and a microstrip line (e.g., the microstrip lines 34 to 37).

The matching circuit 30 according to an embodiment may include a first capacitance component line (e.g., a first capacitance component line 63), a first inductance component line (e.g., a first inductance component line 64) for coupling with the first capacitance component line 63, and a second capacitance component line (e.g., a second capacitance component line 66) for coupling with the first inductance component line 64. For example, the first capacitance component line 63, the first inductance component line 64, and the second capacitance component line 66 may be coupled to be arranged in line. A bond wire 62 (e.g., the bond wires 26 to 29) may receive an output of the multi-channel beamforming chip (e.g., the multi-channel beamforming chip 25 of FIG. 1) through a line 61 and may output the output of the multi-channel beamforming chip (e.g., the multi-channel beamforming chip 25 of FIG. 1) to the first capacitance component line 63. The width of the first capacitance component line 63 and the width of the second capacitance component line 66 may be greater than the width of the first inductance component line 64. For example, in the matching circuit 30, the line width of the first inductance component line 64 may be less than that of the first capacitance component line 63 and may again widen in the second capacitance component line 66. Accordingly, signal loss may be reduced compared to the case where there is no change in the line width. The matching circuit 30 may further include a matcher (e.g., a matcher 65) for performing impedance matching between the first inductance component line 64 and the second capacitance component line 66.

FIG. 4 is a diagram illustrating a converting circuit according to an embodiment.

Referring to FIG. 4, according to an embodiment, the converting circuit 38 may be substantially the same as the converting circuit 38 described with reference to FIGS. 1 and 2. The converting circuit 38 may be substantially the same as the converting circuits 38 to 41, and FIG. 4 only shows the converting circuit 38 for ease of description. The converting circuit 38 may perform conversion to transfer a signal output from a microstrip line (e.g., the microstrip lines 34 to 37 of FIG. 1) to a waveguide 73 (e.g., the waveguide 46). For example, the converting circuit 38 may perform conversion to transfer the signal received from the microstrip line 34 to the waveguide 73. The converting circuit 38 may include at least a part of the microstrip line (e.g., the microstrip line 34). The signal converted by the converting circuit 38 may be transmitted to the waveguide (e.g., the waveguides 46 to 49).

The converting circuit 38 according to an embodiment may include a feeder (e.g., a feeder 71) including at least a part of a ground substrate (e.g., a ground substrate 72) formed in a first structure and the microstrip line (e.g., the microstrip line 34). The ground substrate 72 may be a grounded substrate and may include a metal material. The ground substrate 72 may be configured to maintain straightness of the signal. The ground substrate 72 may be formed in the first structure. For example, the ground substrate 72 may be formed in the first structure in which the end of the microstrip line 34 is bent to form a concavity. The feeder 71 may be formed in a second structure that is able to engage with the first structure. The ground substrate 72 and the feeder 71 may be formed in a structure where the ground substrate 72 and the feeder 71 may be engaged with each other. For example, the feeder 71 may be formed in the second structure having a T-shaped convexity. Since the ground substrate 72 and the feeder 71 are formed in a structure where the ground substrate 72 and the feeder 71 may be engaged with each other, signal loss may be minimized and the signal may be radiated to the waveguide 73. The waveguide 73 may be configured to minimize mixing of external signals and transmitted signals.

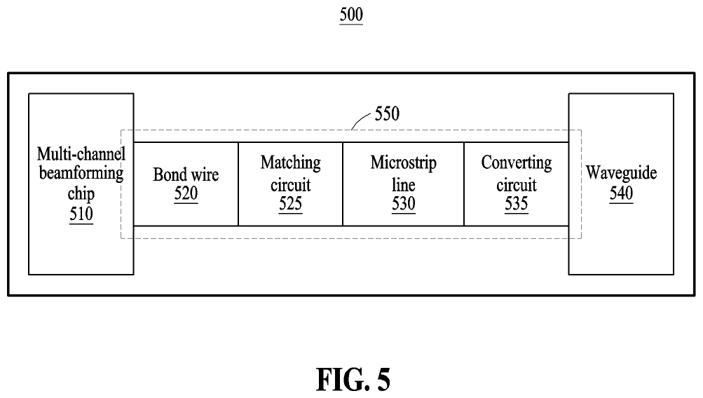

FIG. 5 is a schematic block diagram illustrating a multi-channel beamforming chip-antenna package according to an embodiment.

Referring to FIG. 5, according to an embodiment, a multi-channel beamforming chip-antenna package 500 may be substantially the same as the multi-channel beamforming chip-antenna package 10 described with reference to FIGS. 1 to 4. The multi-channel beamforming chip-antenna package 500 may include a multi-channel beamforming chip 510 (e.g., the multi-channel beamforming chip 25 of FIG. 1) including a plurality of channels (e.g., “n” channels), a waveguide 540 (e.g., the waveguides 46 to 49), and a coupling circuit 550 (e.g., the coupling circuits 110 to 140 of FIG. 1). The coupling circuit 550 may include a bond wire 520 (e.g., the bond wires 26 to 29), a matching circuit 525 (e.g., the matching circuits 30 to 33), a microstrip line 530 (e.g., the microstrip lines 34 to 37), and a converting circuit 535 (e.g., the converting circuits 38 to 41). The multi-channel beamforming chip-antenna package 500 may connect the multi-channel beamforming chip 510 to the waveguide 540 through the coupling circuit 550, thereby transmitting signals over long distances and reducing signal loss. The coupling circuit 550 may reduce loss during signal transmission by arranging the bond wire 520, the matching circuit 525, the microstrip line 530, and the converting circuit 535 in line.

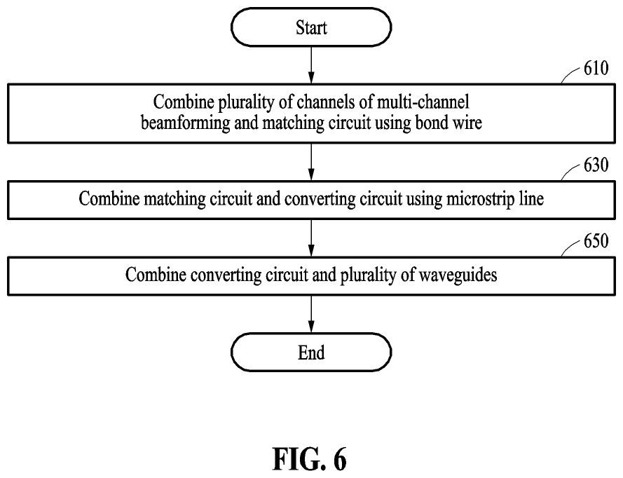

FIG. 6 is a flowchart illustrating a packaging method according to an embodiment.

Referring to FIG. 6, according to an embodiment, a packaging method may be a method of packaging the multi-channel beamforming chip-antenna package 10 described with reference to FIGS. 1 to 5. Operations 610 to 650 according to an embodiment may be performed by a packaging apparatus (not shown). For example, the packaging apparatus (not shown) may manufacture the multi-channel beamforming chip-antenna package 10 by performing operations 610 to 650.

In operation 610, the packaging apparatus according to an embodiment may combine a plurality of channels of a multi-channel beamforming chip (e.g., the multi-channel beamforming chip 25) and a matching circuit (e.g., the matching circuits 30 to 33) using a bond wire (e.g., the bond wires 26 to 29).

In operation 630, the packaging apparatus according to an embodiment may combine the matching circuit (e.g., the matching circuits 30 to 33) and a converting circuit (e.g., the converting circuits 38 to 41) using a microstrip line (e.g., the microstrip lines 34 to 37).

In operation 650, the packaging apparatus according to an embodiment may combine the converting circuit (e.g., the converting circuits 38 to 41) and a plurality of waveguides (e.g., the waveguides 46 to 49).

The components described in the embodiments may be implemented by hardware components including, for example, at least one digital signal processor (DSP), a processor, a controller, an ASIC, a programmable logic element, such as an FPGA, other electronic devices, or combinations thereof. At least some of the functions or the processes described in the embodiments may be implemented by software, and the software may be recorded on a recording medium. The components, the functions, and the processes described in the embodiments may be implemented by a combination of hardware and software.

The embodiments described herein may be implemented using a hardware component, a software component, and/or a combination thereof. A processing device may be implemented using one or more general-purpose or special-purpose computers, such as, for example, a processor, a controller and an arithmetic logic unit (ALU), a DSP, a microcomputer, an FPGA, a programmable logic unit (PLU), a microprocessor, or any other device capable of responding to and executing instructions in a defined manner. The processing device may run an operating system (OS) and one or more software applications that run on the OS. The processing device also may access, store, manipulate, process, and generate data in response to execution of the software. For purpose of simplicity, the description of a processing device is singular; however, one of ordinary skill in the art will appreciate that a processing device may include a plurality of processing elements and a plurality of types of processing elements. For example, the processing device may include a plurality of processors, or a single processor and a single controller. In addition, different processing configurations are possible, such as parallel processors.

The software may include a computer program, a piece of code, an instruction, or some combination thereof, to independently or collectively instruct or configure the processing device to operate as desired. Software and data may be stored in any type of machine, component, physical or virtual equipment, or computer storage medium or device capable of providing instructions or data to or being interpreted by the processing device. The software may also be distributed over network-coupled computer systems so that the software is stored and executed in a distributed fashion. The software and data may be stored in a non-transitory computer-readable recording medium.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specifically designed and constructed for the purposes of embodiments, or they may be of the kind well known and available to those having skill in the computer software arts. Examples of non-transitory computer-readable media include magnetic media such as hard disks, floppy disks, and magnetic tape; optical media such as compact disc read-only memory (CD-ROM) discs and digital video discs (DVDs); magneto-optical media such as optical discs; and hardware devices that are specifically configured to store and perform program instructions, such as read-only memory (ROM), random access memory (RAM), flash memory, and the like. Examples of program instructions include both machine code, such as one produced by a compiler, and files containing higher-level code that may be executed by the computer using an interpreter.

The above-described hardware devices may be configured to act as one or more software modules in order to perform the operations of the above-described embodiments, or vice versa.

As described above, although the embodiments have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

What is claimed is:

1. A multi-channel beamforming chip-antenna package comprising:
a multi-channel beamforming chip including a plurality of channels;
a plurality of waveguides; and
a plurality of coupling circuits configured to combine the plurality of channels with the plurality of waveguides,
wherein each of the plurality of coupling circuits comprises:
a matching circuit configured to combine a wire bonded to each of the plurality of channels and a microstrip line; and
a converting circuit configured to combine the microstrip line and the plurality of waveguides.

2. The multi-channel beamforming chip-antenna package of claim 1, wherein
the matching circuit comprises:
a first capacitance component line;
a first inductance component line combined with the first capacitance component line; and
a second capacitance component line combined with the first inductance component line.

3. The multi-channel beamforming chip-antenna package of claim 2, wherein
a width of the first capacitance component line and a width of the second capacitance component line are wider than a width of the first inductance component line.

4. The multi-channel beamforming chip-antenna package of claim 2, wherein
the matching circuit further comprises a matcher configured to perform impedance matching between the first inductance component line and the second capacitance component line.

5. The multi-channel beamforming chip-antenna package of claim 1, wherein
the converting circuit comprises:
a ground substrate formed in a first structure; and
a feeder including at least a portion of the microstrip line,
wherein the feeder is formed in a second structure which is able to engage with the first structure.

6. A packaging method comprising:
combining a plurality of channels of a multi-channel beamforming chip and a matching circuit using a bond wire;
combining the matching circuit and a converting circuit using a microstrip line; and
combining the converting circuit and a plurality of waveguides.

7. The packaging method of claim 6, wherein
the matching circuit comprises:
a first capacitance component line;
a first inductance component line combined with the first capacitance component line; and
a second capacitance component line combined with the first inductance component line.

8. The packaging method of claim 7, wherein
a width of the first capacitance component line and a width of the second capacitance component line are wider than a width of the first inductance component line.

9. The packaging method of claim 7, wherein
the matching circuit further comprises a matcher configured to perform impedance matching between the first inductance component line and the second capacitance component line.

10. The packaging method of claim 6, wherein
the converting circuit comprises:
a ground substrate formed in a first structure; and
a feeder including at least a portion of the microstrip line,
wherein the feeder is formed in a second structure which is able to engage with the first structure.
